(19) United States
(12) Patent Application Publication
(10) Pub. No.: US 2023/0128739 A1
(43) Pub. Date: Apr. 27, 2023

(54) CMP PROCESS APPLIED TO A THIN SIC WAFER FOR STRESS RELEASE AND DAMAGE RECOVERY

(71) Applicant: STMICROELECTRONICS S.r.l., Agrate Brianza (IT)

(72) Inventors: Agata GRASSO, Tremestieri Etneo (IT); Nicolo' PILUSO, Catania (IT); Andrea SEVERINO, Aci Sant'Antonio (IT); Brunella CAFRA, Mascalucia (IT)

(73) Assignee: STMICROELECTRONICS S.r.l., Agrate Brianza (IT)

(21) Appl. No.: 17/962,090

(22) Filed: Oct. 7, 2022

(30) Foreign Application Priority Data
Oct. 26, 2021 (IT) 102021000027467

(51) Int. Cl. B24B 37/10; H01L 21/02; B24B 37/04; B24B 37/015; B24B 37/30

(52) U.S. Cl. CPC B24B 37/102; H01L 21/02013; H01L 21/02016; B24B 37/044; B24B 37/015; B24B 37/30

(57) ABSTRACT

A Chemical Mechanical Polishing, CMP, process applied to a wafer of Silicon Carbide having a thickness of, or lower than, 200 μm, comprising the steps of: arranging the wafer on a supporting head of a CMP processing apparatus, the wafer having a front side and a back side opposite to one another, the front side housing at least one electronic component and being coupled to the supporting head; deliver a polishing slurry on the wafer, wherein the polishing slurry has a pH in the range 2-3; pressing the back side of the wafer against a polishing pad of the CMP apparatus exerting, by the supporting head, a pressure on the polishing pad in the range 5-20 kPa; setting a rotation of the polishing pad in the range 30-180 rpm, and setting a rotation of polishing head in the range 30-180 rpm; setting and maintaining a CMP process temperature equal to, or below, 50° C.

### BACKGROUND

### Technical Field

The present disclosure relates to a Chemical Mechanical Polishing, CMP, process applied to a thin wafer of Silicon Carbide.

### Description of the Related Art

Integrated circuits are known to be manufactured by alternated steps of deposition and removal of layers belonging to a Silicon and Silicon Carbide wafers; such layers may be either conductive, semiconductive or insulating.

One manufacturing step involves wafer thinning to guarantee optimal device performances, typically a reduction of the electrical resistance when the device is conducting (Rₒₙ resistance). The thinning process is usually performed by mechanical abrasion of a substrate (grinding process).

On SiC wafers, the grinding process may cause deep sub-surface damage, with cracks and dislocations, that extends in depth through the silicon carbide surface for 1-3 μm.

Wafer warpage, caused by a compressive stress on the wafer surface, is also a direct consequence of a thinning process by grinding techniques. Stress induced by thinning process and the persistence of cracks increase wafer warpage and makes the dies thus manufactured fragile, impacting mechanical strength and die yield.

### BRIEF SUMMARY

The present disclosure provides a CMP process applied to a thin wafer of silicon carbide, which, among others, overcome the drawbacks of existing solutions.

According to the present disclosure, a CMP process is applied to a wafer of silicon carbide. For example, the CMP process is applied to a wafer of silicon carbide having a thickness of, or lower than, 180 μm. The CMP process releases the stress of thinned wafers and recover surface damages or cracks. The CMP process is carried out at the back side of SiC wafers having a front side already processed, e.g., with electronic components integrated at the front side.

### BRIEF DESCRIPTION OF THE SEVERAL VIEWS OF THE DRAWINGS

For a better understanding of the disclosure, some embodiments thereof will now be described, purely by way of non-limiting example and with reference to the attached drawings, wherein:

FIG. 1 shows a schematic implementation of a CMP apparatus; and

FIG. 2 shows a portion of a wafer during the CMP processing according to the present disclosure.

### DETAILED DESCRIPTION

A stress relief step able to recover the original (pre-grinding) wafer surface and hence to recover the wafer warpage to the original, pre-grinding, values, can improve silicon carbide material quality and consequently the electrical and mechanical quality of the devices integrated therein.

The present inventors investigated the use of a thermal process, e.g., annealing, to recover the grinding damages; however, this solution is not satisfactory due to thermal constraints that, in some situations, e.g., when the wafer has already been processed to manufacture, at least in part, of electronic devices, limit the temperatures below 1000° C. This thermal budget is not able to guarantee the SiC wafer surface recovery.

Same considerations can be done for laser annealing that allows local surface heating of the wafer; the thermal-induced stress by laser irradiation is responsible for crystal rearrangement, with new crystal defect and possible cracks creation due to the thermal gradient crated during laser processing between an annealed, e.g., thermally stressed, region and a region not subject to annealing.

Therefore, stress release is a particularly critical step for SiC wafers, having low fracture toughness and extreme brittleness, high hardness and a remarkable chemical inertness. These issues become more serious with SiC substrate having reduced thickness, for example under 180 μm.

In an embodiment of the present disclosure, a CMP (chemical-mechanical_polishing) process is proposed.

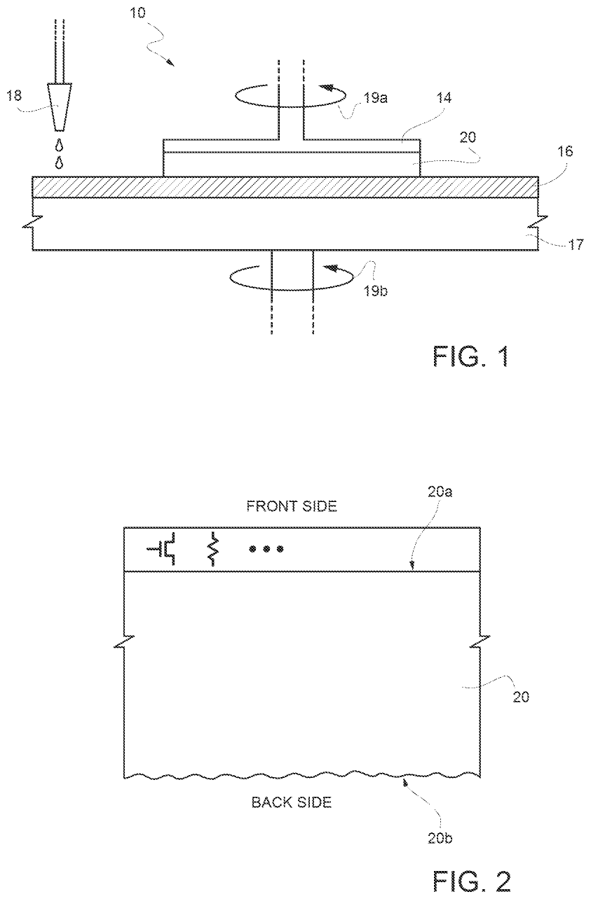

With reference to FIG. 1, a CMP apparatus 10 is schematically shown.

The CMP apparatus 10 comprises a polishing head 14, configured to support or carry or hold a wafer 20 (here, of silicon carbide) during the CMP process. A polishing pad 16 is arranged over a supporting platen 17. The polishing pad 16 is, for example, of polyurethane. The polishing head 14 and the polishing pad 16 faces one another.

Both the polishing head 14 and the platen 17 are controllable in rotation, as illustrated by arrows 19a, 19b, for performing the CMP process. The rotation of the platen 17 causes a corresponding rotation of the polishing pad 16, and the rotation of the polishing head 14 causes a corresponding rotation of the wafer 20.

A slurry delivery system 18 is also provided, configured to provide a substantially uniform slurry layer (e.g., the chemical-mechanical abrasive) onto the polishing pad 16, in a per se known way. After-polishing detection and process control equipment, waste treatment and testing equipment, etc., may also be part of the CMP apparatus 10.

The SiC wafer 20 to be processed has a front side 20a and a back (or bottom) side 20b, opposite to one another. As better discussed in the following, in some embodiments, the front side 20a has already been processed to manufacture one or more electronic devices, or parts therefor, for example by implanting dopant species, growing or depositing conductive or insulating layers, etc. The back side 20b has been subject to a grinding process, to reduce the thickness of the wafer 20 down to 200 μm or less. The CMP process, in some embodiments is applied to the bottom side 20b.

During the CMP process, the wafer 20, supported/held by the polishing head 14 at the front side 20a, is pressed, by the polishing head 14, against the polishing pad 16 to process the surface 20b. For example, the wafer 20 is of silicon carbide (SiC) and has a thickness of, or below, 180 μm, e.g., between 40 and 180 μm, and more for example 100 μm. For example, SiC wafers 20 are manufactured with a thickness of about 350-500 μm; to achieve the thickness of 180 μm or less, a grinding step is carried out, as previously discussed.

As shown in FIG. 2, the front side 20a of the wafer 20 may be already processed to form, at least in part, electronic components or devices, or any other electrical structure. A back side 20b of the wafer 20 is the side processed by the grinding process (and therefore presenting defects/cracks as a consequence of the grinding process), and to be further processed by the CMP process according to the present disclosure.

In some embodiments, the CMP process according to the present disclosure is carried out with the following parameters and settings.

### Polishing Pad Speed and Wafer Speed

Polishing pad speed can affect the entering and leaving of chemical products and reactants between the wafer 20 and the polishing pad 16. The wafer speed will affect the speed of the abrasives through the wafer 20.

The speed of rotation of the polishing pad is set in the range 30-180 rpm, in some embodiments, between 30 and 70 rpm.

The speed of wafer rotation is defined by the speed of rotation of the support carried 14, and is set in the range 30-180 rpm, in some embodiments, between 30 and 60 rpm.

In one embodiment, the wafer 20 (e.g., the carrier 14) and the polishing pad 16 turn to the same direction of rotation; other embodiments, where the wafer 20, e.g., the carrier 14, and the polishing pad 16 turn to the opposite direction are possible.

### Polishing Pressure

Pressure is exerted by the polishing head 14 on the polishing pad 16, with the wafer 20 there between.

In this process, the pressure exerted on different areas of the surface 20b of the wafer 20 could, but not necessarily, be different. The pressure is set in the range between 5 and 20 kPa.

### Polishing Time and Material Removal Rate

Polishing time impact on the material removal rate. The selection of polishing time is according to processing quality requirement and/or quantity (thickness) of material to be removed. If polishing time is too long, the abrasives in polishing slurries may lead to secondary injury to the processed surface.

The thickness of SiC removed at the back side 20b is, in one embodiment, in the range 1-3 μm; accordingly, polishing time/removal rate are set accordingly to achieve this objective.

The present inventor determined that removing about 3 μm of SiC material, in some embodiments, is enough to remove all defects and cracks at the treated surface (in this example, surface 20b).

### Type of Slurry

The abrasive slurry is chosen based on its pH property. In the present process, the slurry is chosen with a pH in the range 2-3 (acid), inclusive.

The slurry flow rate is, in one possible embodiment, less than 100 ml/min.

Removal rate can be set freely, for example equal to, or higher than 10 μm/hr. Lower removal rates, e.g., around 6 μm/hr, are possible.

In some embodiments, the slurries include, for example, alumina-based polishing slurries specifically formulated for the chemical mechanical planarization of Silicon Carbide wafers. These slurries are formulated with permanganate oxidizers, tightly sized engineered nano-particles, and accelerant chemistries that facilitate very low surface finish, defectivity and sub-surface damage on SiC surfaces.

Other types of slurries can be used.

### Process Temperature

The CMP process temperature, e.g., temperature of the polishing pad 16, is maintained below 50° C., for example between ambient temperature (around 24° C.) and 50° C.

With the above parameters in the CMP, the inventors determined that the issues of the known art are overcome.

For example, cracks and damages at wafer's surface are recovered or eliminated. Furthermore, wafer warpage at the end of the CMP process is found to be substantially equal to the original wafer warpage, e.g., before the thinning step performed through grinding.

Surface quality is improved with the CMP process using the parameters discussed herein. The parameters achieve an appropriate balance between chemical and mechanical factors, which can reduce the wafer's roughness so as to obtain higher surface shape precision and ensure the surface quality. The wafer surface 20b after CMP can be inspected through profile testing and its surface roughness can be measured by large area surface profilometer. For the surface quality testing of the wafer, several indexes can be measured. For example, the following parameters have been exemplarily measured: Sa or arithmetical mean height<2 nm; Sq or root mean square height<10 nm; Sz or maximum height<2 nm.

The advantages achieved by the present disclosure are apparent from the above description.

The disclosure proposes a way to solve the difficulty to perform a proper stress relief process after SiC wafers grinding (<180 um) due to the high chemical inertness of SiC. The proposed solution, based on a chemical mechanical surface planarization stress relief process, has demonstrated to be effective on warpage/stress recovery, on surface recovery and mechanical yield. The CMP process step can be performed during a device fabrication process flow, after a grinding step, to recover the damages of the grinding step, thus increasing device yield.

Finally, it is evident that modifications and variations may be made to the present disclosure, without departing from the scope of the disclosure, as defined in the annexed claims.

For example, the CMP process described above can be applied on a SiC wafer that is temporarily bonded to a support wafer, which is useful in case of SiC wafer having low thickness, and therefore being fragile and/or difficult to handle.

A Chemical Mechanical Polishing, CMP, process applied to a wafer (20) of Silicon Carbide having a thickness of, or lower than, 200 μm, may be summarized as including the steps of arranging the wafer (20) on a supporting head (14) of a CMP processing apparatus (10), the wafer (20) having a front side (20a) and a back side (20b) opposite to one another, the front side (20a) housing at least one electronic component and being coupled to the supporting head (14); deliver a polishing slurry on the wafer (20), wherein the polishing slurry has a pH in the range 2-3; pressing the back side (20b) of the wafer (20) against a polishing pad (16) of the CMP apparatus (10) exerting, by the supporting head (14), a pressure on the polishing pad (16) in the range 5-20 kPa; setting a rotation of the polishing pad (16) in the range 30-180 rpm, and setting a rotation of polishing head (14) in the range 30-180 rpm; setting and maintaining a CMP process temperature equal to, or below, 50° C.

The flow rate of the polishing slurry may be less than 100 ml/min.

The polishing slurry may be alumina-based.

The CMP process may be executed until a thickness between 1 and 3 μm of material is removed from the back side (20b) of the wafer (20).

The direction of rotation of the polishing pad (16) may be the same to the rotation of the supporting head (14).

The rotation of the polishing pad (16) may be set in the range 30-70 rpm, and the rotation of polishing head (14) is set in the range 30-60 rpm.

The various embodiments described above can be combined to provide further embodiments. Aspects of the embodiments can be modified, if necessary to employ concepts of the various embodiments to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A method of executing a chemical mechanical polishing (CMP) process on a wafer of silicon carbide, comprising:
arranging the wafer on a supporting head of a CMP processing apparatus, the wafer having a front side and a back side opposite to one another, the front side housing at least one electronic component and being coupled to the supporting head;
delivering a polishing slurry on the wafer, wherein the polishing slurry has a pH value in a range between 2 and 3;
pressing the back side of the wafer against a polishing pad of the CMP apparatus by exerting, via the supporting head, a pressure on the polishing pad in a range between 5 kPa and 20 kPa;
setting a rotation speed of the polishing pad in a range between 30 rpm and 180 rpm, and setting a rotation speed of the polishing head in a range between 30 rpm and 180 rpm; and
setting and maintaining a CMP process temperature equal to or below 50° C.

2. The method of claim 1, wherein the flow rate of the polishing slurry is less than 100 ml/min.

3. The method of claim 1, wherein the polishing slurry is alumina-based.

4. The method of claim 1, wherein the CMP process is executed until a thickness of between 1 μm and 3 μm of material is removed from the back side of the wafer.

5. The method of claim 1, wherein a direction of rotation of the polishing pad is set to be a same as a direction of rotation of the supporting head.

6. The method of claim 1, wherein the rotation speed of the polishing pad is set in a range between 30 and 70 rpm, and the rotation speed of the polishing head is set in a range between 30 and 60 rpm.

7. A chemical mechanical polishing (CMP) method, comprising:
pressing a surface of a silicon carbide wafer against a polishing pad; and
polishing the surface of the silicon carbide wafer by rotating the polishing pad with a polishing slurry and a polishing temperature,
wherein:
the polishing slurry has a pH value in a range between 2 and 3;
a pressure on the polishing pad is in a range between 5 kPa and 20 kPa;
a speed of the rotating the polishing pad is in a range between 30 rpm and 180 rpm; and
the polishing temperature is equal to or below than 50° C.

8. The CMP method of claim 7, comprising rotating the silicon carbide wafer with a rotation speed in a range between 30 rpm and 180 rpm.

9. The CMP method of claim 7, wherein the polishing slurry is delivered with a flow rate less than 100 ml/min.

10. The CMP method of claim 7, wherein the polishing slurry is alumina-based.

11. The CMP method of claim 7, wherein the polishing is executed until a thickness between 1 and 3 μm of material is removed from the surface of the silicon carbide wafer.

12. The CMP method of claim 8, wherein a direction of rotation of the polishing pad is set to be a same as a direction of rotation of the silicon carbide wafer.

13. The CMP method of claim 8, wherein a direction of rotation of the polishing pad is set to be opposite to a direction of rotation of the silicon carbide wafer.

14. The CMP method of claim 8, wherein the rotation speed of the polishing pad is set in a range between 30 rpm and 70 rpm, and the rotation speed of the polishing head is set in a range between 30 rpm and 60 rpm.

15. A method of executing a chemical mechanical polishing (CMP) process on a wafer of silicon carbide, comprising:
arranging the wafer on a supporting head of a CMP processing apparatus, the wafer having a front side and a back side opposite to one another, the front side housing at least one electronic component and being coupled to the supporting head;
delivering a polishing slurry on the wafer, the polishing slurry having a pH value in a range between 2 and 3;
pressing the back side of the wafer against a polishing pad of the CMP apparatus with a pressure on the polishing pad in a range between 5 kPa and 20 kPa;
setting a rotation speed of the polishing pad in a range between 30 rpm and 70 rpm, and setting a rotation speed of the polishing head in a range between 30 rpm and 60 rpm;
setting and maintaining a CMP process temperature in a range between 24° C. and 50° C.

16. The method of claim 15, wherein the flow rate of the polishing slurry is less than 100 ml/min.

17. The method of claim 15, wherein the polishing slurry is alumina-based.

18. The method of claim 15, wherein the CMP process is executed until a thickness of between 1 μm and 3 μm of material is removed from the back side of the wafer.

19. The method of claim 15, wherein a direction of rotation of the polishing pad is set to be a same as a direction of rotation of the supporting head.

20. The method of claim 15, wherein a removal rate of the CMP process is set to be equal to or higher than 10 μm/hr.
